(19) United States
(12) Patent Application Publication
(10) Pub. No.: US 2026/0269768 A1
(43) Pub. Date: Sep. 10, 2026

(54) THERMAL ENERGY RECOVERY COVER PANEL TO PRODUCE ELECTRICITY

(71) Applicant: Cosmo Turano, VICO MORCOTE (CH)

(72) Inventors: Cosmo Turano, Vico Morcote (CH); Elis Mantovani, Breganzona (CH)

(21) Appl. No.: 19/111,184

(22) PCT Filed: Sep. 25, 2022
(86) PCT No.: PCT/IB2022/059066

§ 371 Date: Mar. 12, 2025

(51) Int. Cl. H02S 10/30; H10N 10/13

(52) U.S. Cl. CPC H02S 10/30; H10N 10/13

(57) ABSTRACT

The present invention relates to modular metal panels for thermal energy recovery, with chamber and without chamber usable on buildings or on self-propelled mobile structures or on another kind of prefabricated or non-prefabricated structures, having a metal structure (11) acting as a support for at least a layer (12) of heat-conducting carbonaceous material, coupled to a thermoelectric converter capable of generating electrical energy on the basis of a thermal differential between a first and second surface of said at least one layer (12).

The present invention also relates to a method of manufacturing said panels.

### FIELD OF TECHNIQUE

The present invention refers to the field of metal roofing panels and in detail it concerns a roofing panel with thermal energy recovery (hot or cold) to produce electricity with zero emissions.

### KNOWN ART

It is known that many buildings are covered with panels in different types of material both on the walls and on the roofs. These panels are typically made to improve the insulation of the building's interior.

The panels of the known type do not allow any energy to be recovered, although their external surfaces are subjected to thermal energy from the sun or to thermal energy from the air (hot or cold), which could therefore be used inside the ‘building.

Furthermore, the panels, of the known type, are sensitive to the action of one or more atmospheric phenomena, in particular to the action of eroding agents such as the sand found in desert areas but also in coastal areas and which can also cause abrasion. significant of the surface of the panel itself.

The purpose of the present invention is therefore to describe a thermal energy recovery panel, allowing to solve the drawbacks described above and to produce, at the same time, zero-emission electricity.

### SUMMARY OF THE INVENTION

According to the present invention, modular metal panels with thermal energy recovery are made to produce electricity with zero emissions with a chamber and without a chamber that can be used on buildings or on self-propelled mobile structures or on prefabricated or non-prefabricated structures of any other kind.

The said metal panel for thermal energy recovery to produce zero-emission electrical energy with a chamber comprising a metal structure acting as a support substrate, at least one metal plate or other material on which one or a plurality of said metal structures acting as support substrates. The said metal structure acting as a support substrate comprises a first layer of heat-conducting carbonaceous material; said layer being superimposed on said surface of the metal structure acting as substrate and having an oriented geometric molecular structure, and a thermoelectric converter in contact with said layer of heat-conducting carbonaceous material.

The said metal panel with thermal energy recovery to produce zero-emission electrical energy without a chamber, particularly suitable for buildings, to create a ventilated cover, of walls or roofs, comprising a metal structure acting as a support substrate, a first layer of material carbonaceous heat conductor; said layer being superimposed on said surface of the metal structure acting as substrate and having an oriented geometric molecular structure, and a thermoelectric converter in contact with said layer of heat-conducting carbonaceous material.

Advantageously, said surface of said metal panel comprises at least a second layer of heat-conducting carbonaceous material superimposed on said first layer of heat-conducting carbonaceous material.

In detail, the said thermoelectric converter is positioned on said metal structure acting as a substrate.

In detail, in said converter at least a first layer of carbonaceous material is heat conducting.

In detail, in said converter, the first and second layers of heat-conducting carbonaceous material each have a respective percentage of a bond of the sp² type and of a bond of the sp³ type between the carbon atoms making up said layers of carbonaceous material; said first layer having a percentage of said sp²-type bond and of said sp³-type bond different from the percentage of said sp²-type bond and of said sp³-type bond of said second layer of carbonaceous material.

Advantageously, said thermoelectric converter comprises at least one similar Peltier cell.

More particularly, the said thermoelectric converter comprises a pair of similarly superimposed Peltier cells.

According to the present invention, a method of producing said metal panel, with thermal energy recovery, is carried out to produce electricity with zero emissions, said method comprises a deposition step of at least one layer of carbonaceous material with a geometric structure ordered on of a substrate made of metallic material, in an environment of a deposition machine, said environment being under vacuum and isolated from the external environment in conditions of controlled temperature and pressure; said deposition taking place along an orthogonal or locally radial direction to a plane or shape substantially identified by said substrate made of metallic material.

Advantageously, said deposition step comprises an acquisition step of at least one set of pressure and temperature values within said vacuum and isolated environment.

Advantageously, the said deposition step comprises the generation of an electromagnetic field investing at least partially the said substrate and an automatic control step of the said intensity of the said electromagnetic field by means of a data processing unit of the said deposition machine.

Advantageously, there is also a step of variation of the intensity of said electromagnetic field during a deposition phase of a plurality of superimposed layers of carbonaceous material, in which a variation of a concentration of bonds is produced with said variation of intensity of said electromagnetic field. sp² type and sp³ type of the deposited layer with respect to previously or subsequently deposited layers.

Advantageously, the said method also comprises a step for installing a thermoelectric converter on the panel itself; said thermoelectric converter having at least one surface placed in contact with said at least one layer.

### DESCRIPTION OF THE ATTACHED FIGURES

The invention is now described with reference to the non-limiting annexed figures in which:

FIG. 1 illustrates a section of a metal chamber panel;

FIG. 2 illustrates a section of a metal panel without a chamber;

FIG. 3 illustrates a detail of a portion of a metal panel, with thermal energy recovery, including a device for the transfer of thermal energy;

FIG. 4 illustrates a second alternative embodiment of said metal panel;

FIG. 5 illustrates a schematic representation of a machine for producing the metal panel, of FIGS. 3 and 4;

FIG. 6 and FIG. 7 each illustrate a graph of a process detail of the processing for the purpose of obtaining the panel, according to the present invention, and in detail they concern a graph of density as a function of the thickness of a coating layer in material carbonaceous and a percentage of sp³ type bonds depending on the supply voltage of a metal substrate;

FIG. 8 illustrates a table of thickness values of layers of carbonaceous material.

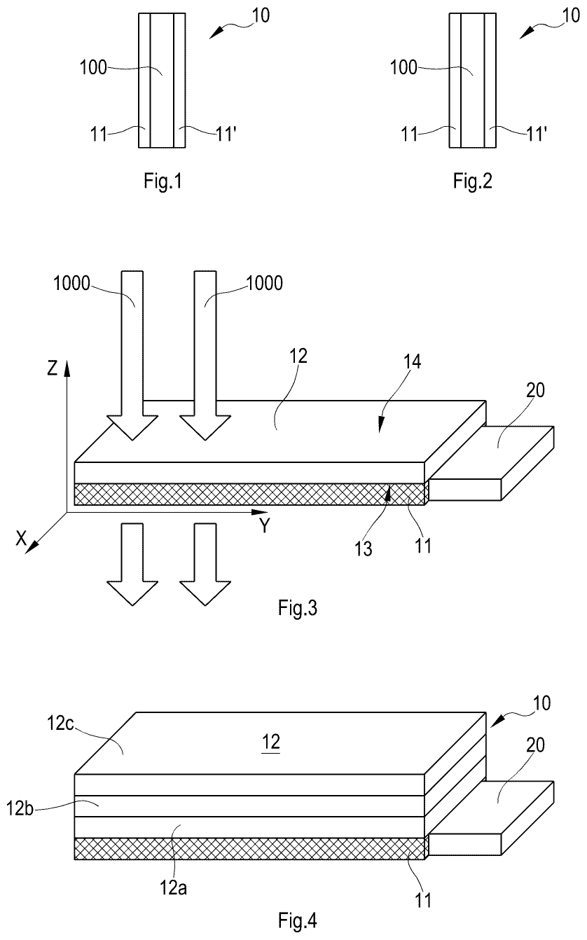

### DETAILED DESCRIPTION OF THE INVENTION

With reference to the attached figures, the reference number 10 indicates as a whole a portion of a metal panel, with thermal energy recovery; this metal panel, which has at least one metal structure acting as a support substrate 11, comprises a layer of carbonaceous material, the details of which are better described in the following of the present description, which is configured to convey the thermal energy in one or more substantially predetermined directions to allow their transformation into electrical energy.

In detail, as shown in the section of FIG. 1, the said panel has, in addition to the metal substrate 11, a metal plate or other material or fixing profiles 11′, thus making a metal panel for thermal energy recovery with a chamber or without chamber (with natural ventilation), which can also reduce heat dispersion and noise transmission.

In detail, the panel 10 comprises a substrate 11, lying on a plane identified by a first pair of axes X, Y, on which at least one layer 12 of carbonaceous material is superimposed, which has an ideally uniform thickness over its entire surface., and which therefore identifies a first face 13 and a second face 14 opposite each other and in detail respectively facing the substrate 11 and outwards. The overlap of the substrate 11 with the layer 12 of carbonaceous material occurs on a Z axis substantially orthogonal to the pair of axes X, Y. For clarity of representation, the thermal energy, which impacts on the panel, is schematically shown in FIG. 3 with the arrow 1000.

The layer 12 allows to create a guide in at least one preferential direction of the thermal energy received at the second face 14 of the layer 12.

In an alternative embodiment, illustrated in FIG. 4, the metal panel object of the present invention comprises several layers 12a, 12b, 12c, each of which is superimposed on the previous one.

Ideally, each of the sp² bonded layers has the same thickness as the other s² bonded layers and each of the sp³ bonded layers has the same thickness as the other sp³ bonded layers.

The metal panel 10, according to the present invention, is made by means of a process which includes a first pre-washing step, in which the substrate 11 is carefully washed, at a Nano metric size, in such a way as to allow the correct growth of the first layer 12 of material. carbonaceous.

In detail, the first pre-wash phase is designed to proceed with the elimination of all micrometric impurities and most of those of Nano metric size.

Since temperatures above 65° C. can be reached during the pre-washing step, it is important that the substrate 11 can also be subjected to these temperatures without being damaged.

Specifically, the pre-washing phase is performed in a first alternative solution by:
a preventive covering of the surface of the substrate with acetone;
a subsequent rubbing step by means of a pad;
a subsequent rinsing step, preferably carried out using isopropyl alcohol (propan-2-ol);
a subsequent drying step of the substrate by means of a nitrogen gun (N₂);

Alternatively, the cleaning phase can comprise, in addition to or in place of one or more of the previous phases:
an oxygen plasma etching phase (etching process), which removes residual organic films;
a technical phase of RCA Clean, which removes metal, oxide and organic contaminants, and is carried out in two phases: a first organic cleaning phase, which advantageously removes organic insoluble contaminants with a 5:1:1 solution of H₂O: H₂O₂: NH₄OH; and a second phase called “Oxide Strip”, in which a thin layer of SiO₂ is removed in which metal contaminants may have accumulated.
a phase called “piranha clean” or “piranha etch”, which removes organic materials (photoresist, oils, etc.) and which is obtained by mixing 98% of H₂SO₄ and 30% of H₂O₄ in volumes 2-4: 1, and to which is followed by heating the substrate thus cleaned to 100° C.;
an ultrasonic cleaning phase, in which the substrate is placed in an ultrasonic washing machine and these ultrasound remove the contaminants.

It has been observed in the course of experiments that the optimal solution for cleaning the substrate 11 includes immersion in a Piranha solution (H₂SO₂: H₂O₂, 7:3 for 10′), followed by ultrasonic cleaning.

Finally, at the end of the cleaning phase, a deposition phase on the substrate 11 always follows in an HV or UHV chamber, in which it is cleaned with low energy etching to avoid amorphization. At this point the substrate is ready to be processed.

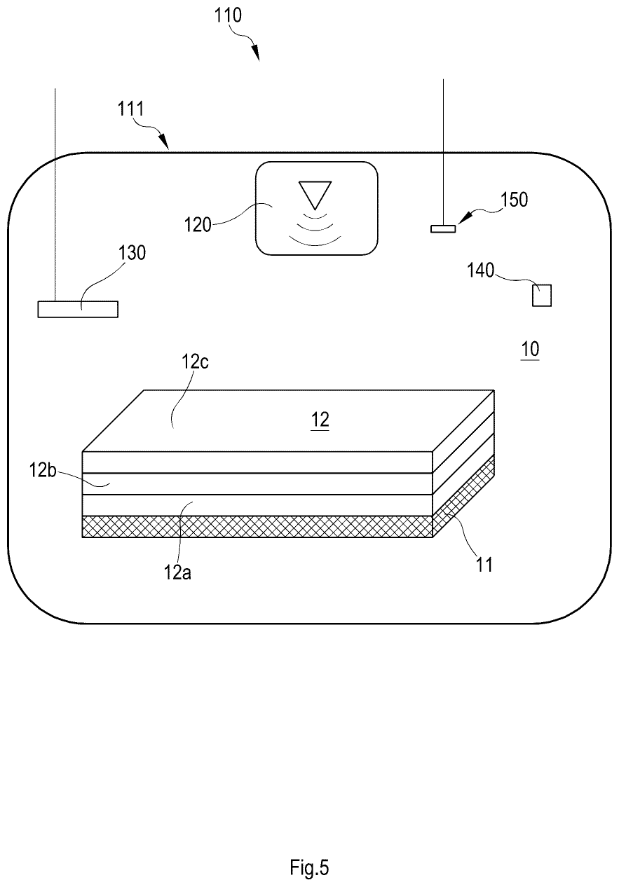

The process then continues in the vacuum chamber 111 (FIG. 5) of a deposition machine 110 (FIG. 5); within the vacuum chamber, through a molecular vacuum pump that sucks the air from the inside, a threshold pressure is reached (preferably less than 10⁻¹ Pa) following which a deposition phase of one or more layers 12 of carbonaceous material takes place In detail, the deposition machine 110 comprises at least one mobile magnetron sputtering 120, a system for gripping and moving the substrate, positioned inside the vacuum chamber 111 and a gas inlet 150 also with an end positioned in said vacuum chamber. The vacuum chamber 111 creates a clean environment, isolated from the outside, in which the following deposition phase takes place under optimal conditions of temperature and pressure managed and controlled according to the process.

During the deposition phase, the magnetron 120 is activated and produces an electromagnetic field which strikes the substrate 11 in a precise way during its translation along a plane substantially parallel to the X, Y plane identified by the substrate 11.

Substantially therefore, a relative movement takes place between the magnetron 120 and the substrate 11 on an X, Y plane, which allows a deposition of the carbonaceous material in a much more precise way than with a traditional sputtering technique.

Also inside the vacuum chamber 111 there is an electron gun 130 which transmits a beam of electrons against a target in carbon 140 of a preferably although not limitedly planar type positioned in contact with an electrode. Carbon atoms branch off from the carbon target 140 and are directed towards the substrate 11.

In detail, the target 140 was selected as 99.99% pure graphite, in order to obtain a coating with a crystalline structure that has characteristics similar to diamond.

The purity of the graphite with a value of 99.99% facilitates the obtaining of the deposition of layers 12 of high efficiency carbonaceous material, and to avoid spreading impurities inside the vacuum chamber 111 which can significantly reduce the overall efficiency of the device.

The magnetron 120 is activated together with the simultaneous entry into the chamber of gas for deposition, comprising preferably and not limitedly Ar gas (Argon) with a small percentage of H₂ (hydrogen)

The deposition phase may include one or more deposition steps of a layer 12 of carbonaceous material, depending on the thickness to which you want to bring the set of layers 12 that may be present overall.

In detail, in fact, with a single deposition step, the deposition machine 110 allows the deposition of a layer 12 of carbonaceous material having a thickness—measured along the Z axis—equal to 100 nm. However, through multiple deposition steps, further uniform layers are superimposed on each layer 12 of carbonaceous material until a thickness of 6 μm is reached.

The number of layers 12 of carbonaceous material allows to determine a priori the amount of thermal energy that the device 10 (metal panel for thermal energy recovery) according to the present invention is able to transfer.

Preferably, a cooling interval is left between one deposition step and the next; this allows the temperature to be kept below values likely to cause a reduction in the performance of the device 10 (metal panel with thermal energy recovery).

During the deposition step, the substrate 11 can optionally be subjected to an electrical voltage greater or less than zero, which, as described below, can in some cases even reach several hundreds of Volts. This voltage is called “bias voltage” in technical jergo. This helps in detail to favour the deposition process of the carbonaceous material on the substrate 11 and, by varying the electrical voltage to which the substrate is subjected, the percentage of sp² bonds—typical of graphite—is varied in relation to the percentage of sp³ bonds—typical of the diamond—which will occur in the layer of carbonaceous material deposited.

According to the present invention, by sp² or sp³ type bonds are meant those bonds generated by the hybridization process, which takes place on a predetermined number of orbitals (s, p, d orbitals) with slightly different energy content; this bond allows to obtain new equivalent hybrid orbitals (isoenergetic) with lobes oriented along the directions of the possible bonds that the central atom of one or more molecules can form with other atoms. In detail, three orbitals are involved in the sp² type orbitals, one of which is of type s and two of type p; vice versa, in the case of the sp³ type bond, there is the hybridization of four orbitals, one of which is of type s and three of type p. In particular, during the deposition phase, the carbonaceous material assumes a substantially crystalline shape with an ordered geometric structure, similar to that of a diamond; in particular, through the use of the magnetron 120 a geometric structure is recreated which in a first and simpler form of implementation of the deposition process are oriented in the same direction.

This means that during the various deposition steps of carbonaceous material, the bias voltages on the substrate 11 can be varied, consequently varying the crystalline form of the carbonaceous material from layer to layer and consequently the characteristics of strength, density and quantitative thermal transport capacity for each layer.

In detail, in the crystalline form desired for application on the device of the present invention, carbon has a prevalence of sp³ type bonds, typical of diamond, rather than sp² type bonds typical instead of graphite. In particular, the crystal structure is of the tetrahedral type.

It is preferable to have a deposition of several layers of carbonaceous material with a height along the thin Z axis rather than having a single layer of carbonaceous material with a high height;

In fact it has been seen that by reducing the height of each layer of carbonaceous material deposited on the substrate 11, and in particular by keeping it below 100 nm per layer, it is possible to reduce both the mechanical stress and the temperature of the layer itself, advantageously having a reduction of the percentage of sp²-type bonds typical of graphite, to the advantage of the mechanical resistance and a higher thermal conductivity.

Finally, further experiments have shown that the absolute highest thermal transfer efficiency is found when successive superimpositions of at least two and preferably more layers 12 of carbonaceous material with a prevalence of sp³-type bonds are carried out separated by at least one layer 12 of carbonaceous material with a prevalence of sp²-type bonds.

The described deposition process is advantageously capable of leaving the physical characteristics of the support substrate unaltered, advantageously adding the characteristic of high thermal conductivity such as to ensure high speed of transfer of thermal energy.

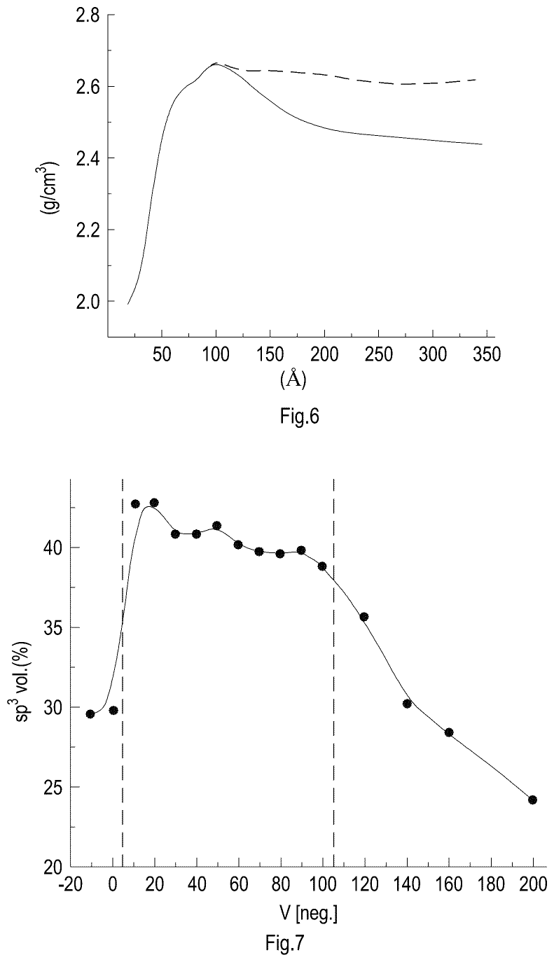

As illustrated in FIG. 6, in fact, depending on whether a single layer of carbonaceous material is used or several layers superimposed on the substrate 11 in distinct deposition passages, the density characteristics of the material change. The diagram of FIG. 6 illustrates in detail a structure in which the substrate 11 has been subjected to a bias voltage of −20V, both with a single deposition phase (solid line) and with several deposition phases (dashed line).

Now, from this graph in FIG. 6, it can be observed how the rapid growth in density for the lower thicknesses along the Z axis indicates the presence of a few micro voids, an index of the generation of sp³-type bonds.

Having reached about 70 Angstroms, depending on whether there is a single layer or more layers of carbonaceous material, the density changes as the thickness increases, reducing in the case of the single layer to a value tending to about 2.44 g/cm³, while in the case of several layers it remains in the order of over 2.6 g/cm³.

This occurs because the continuous exposure of the substrate 11 and layer 12 of carbonaceous material to the action of ion bombardment causes an increase in temperature inside the layer 12, and consequently increases the percentage of sp² bonds.

FIG. 7 instead illustrates in detail how the variation of the bias voltage on the substrate 12 favors the formation of bonds of the sp² or sp³ type. The graph in question shows that between −20V and 0V the percentage of sp³ bonds remains approximately stable around 30% and then drastically increases at the interval between 0 and 20V, stabilizing around 45% and then decaying between about 40% and 38% in the range substantially between 30V and 100V.

Beyond this bias voltage value, a more rapid decay of the percentage of sp³ bonds is observed, which, except for a brief inflection, decreases linearly to just under 20% at a bias voltage equal to 200V.

The graph of FIG. 7 can therefore be divided into three zones, a first (I) in which with bias voltages between −20V and 0V there is no ionic bombardment by the carbon, which is deposited gently on the substrate 11, which is subject only to the action of the technical gas introduced into the vacuum chamber 111; the carbon deposition therefore takes place in a condition of near equilibrium. Subsequently there is a second zone (II) [0-100] V, in which an ionic sub-implantation mechanism is activated in the substrate, and a third zone (III) [100-200] V in which a thermalization process is activated.

It should be noted that the voltages indicated in the graph are actually negative, i.e. the first zone actually corresponds to a positive substrate voltage.

An experiment was carried out in which layers of sp² or sp³ type material overlap; a first layer 12 (said layer A) is deposited on the substrate 11 fed with a bias voltage equal to 10V (V_{b}=−10V); a second layer 12 (said layer B) is deposited by feeding the substrate 11 with a bias voltage equal to −20V, and each layer is deposited in one, two or three substrates with a total thickness between dₐ and d_{b}.

The total product thickness is equal to 900-1000-2600 Angstrom (90-100-260 nm).

The first deposition consists of a bilayer with dA1~150 Å, dB1~230 Å. From the second to the ninth deposition dA1~50 Å. The total thickness is equal to 2620 Å (262 nm).

The content of sp³ depends on V_{b}. The first deposited layer A1 shows a low stress (1.35 GPa) and ensures good adhesion to the substrate 11. The first layer B1, deposited on A1, shows an increase in tension up to 4.5 GPa. Subsequent depositions of layers 12, both A and B have little influence. Above 1800 Å of thickness the stress saturates at 5.2 GPa.

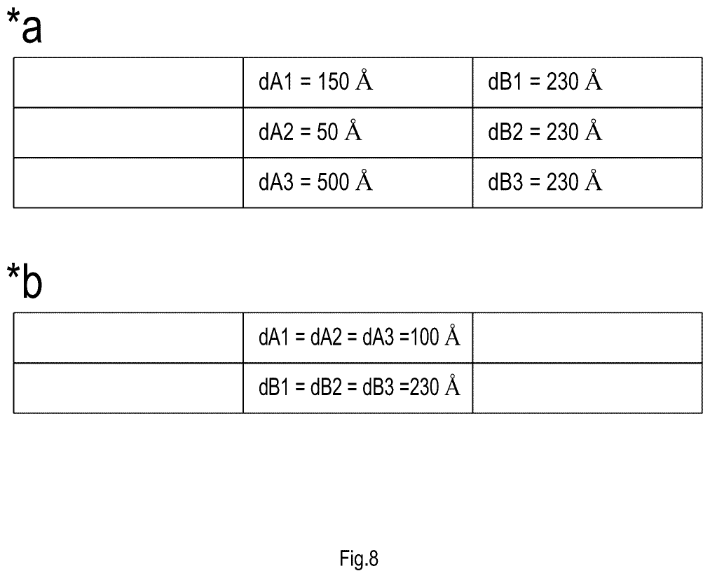

In order to evaluate the effect of layers A on the average stress of the coating, the following group of layers 12 of carbonaceous materials a-C was deposited: *a (~900 Å) and *b (~1000 Å). The thickness data are shown in the table in FIG. 8.

Some deposition “recipes” are reported below which, in the course of the experiments carried out, have shown to allow the realization of particularly effective devices according to the present invention.

A first recipe, performed by sputtering with Magnetron on the machine described above, includes:
target 140:99.9999% pure graphite with a thickness of 10 mm (indicative) and diameter 75÷90 mm (indicative).
gases introduced into the vacuum chamber 111: CH₄;
pressure inside the vacuum chamber 5*10⁻³ Torr;
total gas flow=70 SCCM, Standard Cubic Centimetres per Minute (cm³/min).
Magnetron parameters set: f=13.56 MHz; Power=150 W.

The first recipe identified above made it possible to produce devices whose overall coatings, of a plurality of layers, are for example having a thickness of 300 nm; 600 nm; 1 μm; 3 μm; 6 μm; 10 μm; 20 μm.

A second recipe performed with pulsed bipolar asymmetric sputtering type includes:
target 140:99.9999% pure graphite with a thickness of 10 mm (indicative) and diameter 75÷90 mm (indicative).
gases introduced into the vacuum chamber 111: Ar+7.5% CH₄;
pressure inside the vacuum chamber 9.75*10⁻³ Torr;
Magnetron parameters set: Power density=4.4 W/cm²;
Characteristics of the Pulsed DC signal on the Magnetron 120: Positive pulse +37.5 V; Negative impulse—(600÷700) V; Source used=ENI RPG-50 (indicative); Duty cycle=70%, obtained from a frequency of 150 kHz, with a positive pulse of 2016 ns; substrate bias voltage (−300÷0) V.

The second recipe identified above has made it possible to produce devices whose overall coatings, of a plurality of layers, are for example having a thickness of 300 nm; 600 nm; 1 μm; 3 μm; 6 μm; 10 μm; 20 μm.

A third recipe performed with a sputtering with Magnetron is characterized instead by having the following parameters:
target 140:99.9999% pure graphite with a thickness of 10 mm (indicative) and diameter 75÷90 mm (indicative).
gas introduced into the vacuum chamber 111: Ar+H₂ (0.7%);
pressure inside the vacuum chamber 110:30*10⁻³ Torr;
total flow inside the vacuum chamber 40 SCCM Standard Cubic Centimetres per Minute (cm³/min).
power set on the magnetron: 200 W

The third recipe identified above has made it possible to produce devices whose overall coatings, of a plurality of layers, are for example having a thickness of 300 nm; 600 nm; 1 μm; 3 μm; 6 μm; 10 μm; 20 μm.

Additional recipes have been developed using carbon nanotubes to make the layer or layers of carbonaceous material.

In particular, a first further recipe included the use of a magnetron sputtering on:
target 140 in a mixture of graphite (size of the powder 20÷80 nm) with the addition of 0.5% of Ni powder with dimensions of 60÷100 nm.
gases introduced into the vacuum chamber 111:99.999% pure N₂;
vacuum chamber pressure: 0.075 Torr;
total gas flow: 30 SCCM Standard Cubic Centimetres per Minute (cm³/min).
magnetron parameters set: power 80 W.

A further variant second recipe using nanotubes, through the technique called RF-DC bias Sputtering was performed:
bombarding a target 140 with 99.9999% pure graphite+Ni.
catalyst agent: coating layer or coating of 10 nm of Ni previously deposited on the substrate.
gases introduced into the vacuum chamber 111:99.999% pure N₂;
vacuum chamber pressure: 0.020 Torr;
total gas flow: 30 SCCM Standard Cubic Centimetres per Minute (cm³/min).
magnetron parameters set: power 100 W; substrate bias supply voltage: −20V.

The deposition process is advantageously able to leave unaltered the physical characteristics of the substrate that creates the support (modular metal panel with thermal energy recovery). This is particularly important since the supporting substrate making the modular metal panel with thermal energy recovery must satisfy all the functions for which it was designed. Specifically, said panel, in addition to recovering thermal energy, also acts, albeit not limitedly, as an insulating cover for the walls of buildings or roofing or covering for mobile self-propelled structures or for other types of prefabricated or non-prefabricated structures, therefore it must comply with the physical, dimensional and mechanical resistance characteristics foreseen and defined for the specific application.

Through the process described, to the carbonaceous material coating and therefore to the modular metal panel with thermal energy recovery is given a high resistance to chemical agents and abrasive agents so that the functionality and efficiency of the Nano coating remain unchanged over time..

Advantageously, therefore, the transport of thermal energy offered by the device 10 according to the present invention is of the anisotropic type and therefore has a preferential direction. However, this should not be understood in a limiting way, since it is possible to obtain different preferential directions for each layer 12 of carbonaceous material which is deposited on the previous one.

The machine 110 is equipped with a data processing unit and a plurality of sensors positioned inside the vacuum chamber 111, electrically connected to the said data processing unit, which drives—directly or through servo systems—at least: the amount of energy and the frequency emitted by the magnetron(s), the flow and pressure of the gas(s) inside the vacuum chamber 111 where it is also possible to dynamically vary the temperature T both inside the process chamber and the panel metal T_{sub} to be coated.

In detail, the quantity E of energy and the frequency emitted by the magnetron(s) and the flow F of the gas(s) are varied according to at least two parameters: the temperature of the substrate T_{sub} and the residual pressure inside the vacuum chamber P_{c}, therefore the data processing unit implements a retro-activated control in which at each instant of time the values of the quantity E of energy and of the flow F of the gas(s) are corrected according to the parameters mentioned above in order to keep the thickness uniform and the type, sp² or sp³, of the deposition of the layer 12 of carbonaceous material.

In particular, at least one capacitive type pressure sensor is preferably part of the plurality of sensors electrically connected to the data processing unit.

For each type of substrate 11 the data processing unit is configured to start the deposition phase with a predefined set of parameters (E, Hz, F, T, T_{sub}), which is then adapted according to the data collected by the assembly of sensors positioned inside the vacuum chamber 111 during the carrying out of the deposition step itself.

This guarantees a higher qualitative repeatability of the process, particularly useful if more devices 10 are to be produced in series and have the same operating characteristics.

In use, the layer(s) of carbonaceous material allow to transport thermal energy in the presence of a thermal differential between its substrate 11 and the second face of the upper carbonaceous material layer. In particular, the structure of the layer or layers of carbonaceous material is such as to have a higher thermal transmittance than that of the surrounding environment, creating a sort of thermal superconductor.

In this way, thermal dispersion is minimized, for example by radiation towards the environment surrounding the device itself or even by contact of the device with a foreign body.

From some experiments carried out on a sample whose effective part for the transport of thermal energy is equal to about 10×10 mm, in which the layer of carbonaceous material is equal to 200 nm, with a thermal differential of 50° C. between the side of the substrate 11 and the exposed side of the carbonaceous material layer by means of a thermal imaging camera that showed and it was detected an average thermal conductivity in the measurements of 1570 W/(m·K) with a maximum peak recorded of 1750 W/(m·K).

A thermoelectric converter 20 is installed in contact with a portion of the surface of the panel 10, capable of converting thermal energy into electrical energy. Conveniently, the thermoelectric converter 20 can be applied in correspondence with a portion of one side of the panel 10, thus realizing a conversion system of thermal energy into electrical energy.

The thermoelectric converter 20 is preferably made by means of a plurality of micro cells, similarly, of Peltier, through which the overall efficiency achieved by the system in the electrical thermal conversion can reach peaks of 55% with averages equal to 40%.

The thermoelectric converter 20, which in detail has its first surface 20f directly in contact with a portion of the surface of the coated panel, is configured to generate electric current starting from the thermal differential that is established between the internal part of the panel and the external part. of the panel. The layer or layers 12 must be applied in use on the external face of the panel, or the one that faces the thermal energy of the external environment of buildings or self-propelled mobile structures or other prefabricated or non-prefabricated structures.

Taking into consideration a panel according to the present invention, it has been observed that with particularly efficient thermoelectric converters, with a temperature differential equal to 50° C., having an exposed surface equal to 1 sqm, electric powers even equal to 4000 W are obtained, which decrease at 2700 W if the temperature differential is 40° C. , at 1150 W if the temperature differential is 30° C., at 550 W if the temperature differential is 10° C. or 300 W if the temperature differential is 5° C.

If the panel is not subjected to a thermal differential sufficient to produce energy, an at least temporary thermal imbalance can be triggered by an electrical energy source with the following procedure: by feeding the thermoelectric converter with an electric current, the converter itself will be subject to a temperature variation likely to cause the transfer of thermal energy between the layers of carbonaceous material present on the substrate. This energy injection can be used as a starting condition of imbalance for the initiation of a transfer of thermal energy from the outermost surface of the carbonaceous material layer towards the thermoelectric converter 20. A particularly efficient solution for configuring the cells similarly to Peltier is achieved by overlapping a pair of thermoelectric converters 20, in which each thermoelectric converter 20 has a first face or upper surface (technically definable as a “hot” face) and a second face or lower surface (technically definable as a “cold face” ”), and in which the second lower face of the first thermoelectric converter of said pair rests or in any case faces the first upper face of the second thermoelectric converter of said pair.

Advantageously, this allows to recover part of the dissipated thermal energy coming from the first thermoelectric converter on the second thermoelectric converter. It has also been noted that the panel, treated through the addition of carbonaceous material as described above, is much less subject to dirt, since the part of the layer 12 facing outwards (not facing other layers or the substrate) is very smooth (with very few micro voids) and is also practically immune to the action of external agents such as sand which is often found in desert environments but also in coastal areas and which can cause even significant abrasion of the surface of the panel itself.

Advantageously, therefore, the panel, object of the present invention can be used for applications in desert or coastal environments, in order to contribute to the regularization of the internal temperature of buildings without suffering damage from sandstorms, notoriously capable of scratching (by sandblasting) traditional surfaces due to the abrasive action of the sand raised by the wind.

Advantageously, the panel object of the present invention can be used for applications in extreme Arctic and Antarctic environments dominated by the great cold, in order to contribute to the regularization of the internal temperature of buildings without any damage due to low temperatures and without interruption of the supply of electricity in absence of light and of direct solar radiation.

Conveniently, the thermoelectric converter has at least one surface in contact with the said layer of carbonaceous material to maximize the thermal energy recovery effect, and is advantageously installed on at least one side of the panel in such a way as to be protected.

Finally, it is clear that modifications, additions and variants, obvious to a person skilled in the art, can be applied to the panel, object of the present invention, without thereby departing from the scope of protection provided by the attached claims.

1. Metal panel with thermal energy recovery comprising a metal structure acting as a support substrate (11), at least a first layer of heat-conducting carbonaceous material (12; 12a-12c) having an oriented geometric molecular structure, and a thermoelectric converter in contact with said layer of heat-conducting carbonaceous material.

2. Panel according to claim 1, comprising at least a second layer of heat-conducting carbonaceous material superimposed on said first layer of heat-conducting carbonaceous material.

3. Panel according to claim 1, comprising at least one metal or other material plate, separated from said first support substrate by an insulated chamber.

4. Panel according to claim 1, wherein said thermoelectric converter is positioned on at least one side of the panel.

5. Panel, according to claim 1, in which said at least one first layer of heat-conducting carbonaceous material is dirt-repellent and resistant to abrasion, giving properties of resistance to corrosion.

6. Panel, according to claim 2, wherein said first and said second layer of heat-conducting carbonaceous material (12a-12c) each have a respective percentage of an sp2-type bond and an sp³-type bond between the carbon atoms composing said layer of carbonaceous material, said first layer having a percentage of said sp²-type bond and of said sp³-type bond different from the percentage of said sp²-type bond and of said sp³-type bond of said second layer of carbonaceous material.

7. Panel according to claim 1, wherein said thermoelectric converter comprises at least one cell of the type similar to a cell of the Peltier type.

8. Panel according to claim 1, wherein said thermoelectric converter comprises a pair of superimposed Peltier-like cells.

9. Method for producing a thermal energy recovery panel according to claim 1, said method comprising a deposition step of at least one layer (12; 12a-12c) of carbonaceous material with structure ordered geometry on a substrate (11) made of metallic material in an environment (111) of a deposition machine (110), said environment being vacuum-sealed and isolated from the external environment under controlled temperature and pressure conditions, said deposition occurring along an orthogonal or locally radial direction to a plane or shape substantially identified by said substrate (11) made of metallic material.

10. Method according to claim 7, wherein said deposition phase comprises an acquisition step of at least one set of pressure and temperature values within said isolated environment (111).

11. Method according to claim 7, wherein said deposition phase comprises the generation of an electromagnetic field investing at least partially the said substrate (11) and an automatic control step of the said intensity of the said electromagnetic field by means of a data processing unit of said deposition machine (110).

12. Method according to claim 8, further comprising an installation step of a thermoelectric converter on at least one side of the panel; said thermoelectric converter having at least one surface placed in contact with said at least one layer (12).

13. A method according to claim 7, further comprising a step for varying the intensity of said electromagnetic field during a deposition step of a plurality of superimposed layers (12a-12c) of carbonaceous material, in which with said variation of intensity of said electromagnetic field a variation of a concentration of sp2 and sp3 bonds of the deposited layer with respect to previously or subsequently deposited layers is produced.
